(19) United States
(12) Patent Application Publication
(10) Pub. No.: US 2026/0346626 A1
(43) Pub. Date: Nov. 5, 2026

(54) INKJET PRINTING APPARATUS, METHOD OF DRIVING THE SAME AND ELECTRONIC DEVICE MANUFACTURED USING THE SAME

(71) Applicant: Samsung Display Co., Ltd., Yongin-si (KR)

(72) Inventors: Mamoru WAKABAYASHI, Yokohama-shi (JP); SATOSHI TOMOEDA, Yongin-si (KR)

(21) Appl. No.: 19/540,480

(22) Filed: Feb. 13, 2026

(30) Foreign Application Priority Data
May 1, 2025 (JP) 2025-076131

(51) Int. Cl. B41J 25/308; B41J 2/165; B41J 2/21

(52) U.S. Cl. CPC B41J 25/308; B41J 2/16526; B41J 2/2103

(57) ABSTRACT

An inkjet printing apparatus includes: a stage; a support table on the stage and to which a target substrate is fixed; a first mover configured to move the support table in a first-axis direction on the stage; a head component on the target substrate and including an inkjet head configured to eject ink onto a printing area of the target substrate; and a second mover configured to move the head component in a second-axis direction, and wherein the head component is configured to receive print image data including a position signal indicating a position of the support table and information on a correction amount of the position signal, and to correct the position signal based on the correction amount.

### CROSS-REFERENCE TO RELATED APPLICATION

The present application claims priority to and the benefit of Japanese Patent Application No. 2025-076131, filed on May 1, 2025, in the Japan Patent Office, the entire disclosure of which is incorporated herein by reference.

### BACKGROUND

Aspects of some embodiments of the present disclosure described herein relate to an inkjet printing apparatus, a method of driving the same, and an electronic device manufactured using the same.

Multimedia devices such as televisions, mobile phones, tablet computers, navigation systems, game consoles, and the like may be equipped with a display panel for displaying images. The display panel may include a plurality of pixels for displaying an image, each of which may include a light emitting element that generates light and a driving element connected to the light emitting element.

Inkjet printing apparatuses are used in the manufacture of display panels. The inkjet printing apparatuses may form a desired layer on a display panel by printing an organic material (or ink) onto a substrate.

High-resolution and precise patterning processes may be utilized in the manufacture of display panels. As a pixel size of the display panel decreases due to higher resolution, the inkjet printing apparatus may desirably eject a smaller amount of ink. When the amount of ink ejected by the inkjet printing apparatus is not precisely controlled, defects may occur.

The above information disclosed in this Background section is only for enhancement of understanding of the background and therefore the information discussed in this Background section does not necessarily constitute prior art.

### SUMMARY

Aspects of some embodiments of the present disclosure include an inkjet printing apparatus with a relatively reduced defect rate, a method for operating the same, and an electronic device manufactured using the same.

According to some embodiments of the present disclosure, an inkjet printing apparatus includes a stage, a support table on the stage and to which a target substrate is fixed, a first moving unit that moves the support table in a first-axis direction on the stage, a head unit on the target substrate and including an inkjet head that ejects ink onto a printing area of the target substrate, and a second moving unit that moves the head unit in a second-axis direction. According to some embodiments, the head unit receives print image data including a position signal indicating a position of the support table and information on a correction amount of the position signal, and corrects the position signal based on the correction amount.

According to some embodiments of the present disclosure, a method of driving an inkjet printing apparatus includes receiving print image data through a head unit, extracting a first command from the print image data and determining whether to initiate a compensation setting operation based on the first command, when the compensation setting operation is initiated, extracting a correction amount from the print image data and storing the extracted correction amount in a parameter storage unit, masking the entire print image data through a mask unit to generate entire masking data, extracting a second command from the print image data and determining whether to terminate the compensation setting operation based on the second command, and when the compensation setting operation is not initiated, masking portions of the print image data indicating the first and second commands through the mask unit to generate compensation print image data.

According to some embodiments of the present disclosure, an electronic device includes a display module that displays an image, and a processor that processes an image signal so as to provide to image data the display module.

According to some embodiments, the display module is manufactured using an inkjet printing apparatus.

According to some embodiments, the inkjet printing apparatus includes a stage, a support table on the stage and to which a target substrate is fixed, a first moving unit that moves the support table in a first-axis direction on the stage, a head unit on the target substrate and including an inkjet head that ejects ink onto a printing area of the target substrate, and a second moving unit that moves the head unit in a second-axis direction. According to some embodiments, the head unit receives print image data including a position signal indicating a position of the support table and information on a correction amount of the position signal, and corrects the position signal based on the correction amount.

### BRIEF DESCRIPTION OF THE DRAWINGS

The above and other aspects and features of embodiments according to the present disclosure will become apparent by describing in more detail aspects of some embodiments thereof with reference to the accompanying drawings.

FIG. 1 is a perspective view of an electronic device, according to some embodiments of the present disclosure.

FIG. 2 is an exploded perspective view of an electronic device, according to some embodiments of the present disclosure.

FIG. 3 is a cross-sectional view of a display module, according to some embodiments of the present disclosure.

FIG. 4A is a cross-sectional view of a display module, according to some embodiments of the present disclosure.

FIG. 4B is an enlarged cross-sectional view of a portion of a display module, according to some embodiments of the present disclosure.

FIG. 5 is a cross-sectional view illustrating one step of a method for manufacturing a display module, according to some embodiments of the present disclosure.

FIG. 6A is a plan view illustrating an inkjet printing apparatus, according to some embodiments of the present disclosure.

FIG. 6B is a plan view illustrating an example of an inkjet head illustrated in FIG. 6A.

FIG. 7 is a block diagram of an inkjet printing apparatus, according to some embodiments of the present disclosure.

FIG. 8 is a plan view illustrating first to k-th print images, which are images of print image data, according to some embodiments of the present disclosure.

FIG. 9A is a graph illustrating a position error of a first inkjet head and a second inkjet head among inkjet heads, according to some embodiments of the present disclosure.

FIG. 9B is an enlarged graph illustrating area A1 illustrated in FIG. 9A.

FIG. 9C is an enlarged graph illustrating area A2 illustrated in FIG. 9A.

FIG. 10A is a waveform diagram illustrating correction position signals corresponding to first and second compensation sections illustrated in FIG. 9B, respectively.

FIG. 10B is a waveform diagram illustrating correction position signals corresponding to 81st and 82nd compensation sections illustrated in FIG. 9C.

FIG. 11 is a flowchart illustrating an operation of an inkjet printing apparatus, according to some embodiments of the present disclosure.

FIG. 12 is a block diagram of an electronic device according to some embodiments.

FIG. 13 is a schematic diagram illustrating electronic devices, according to various embodiments.

### DETAILED DESCRIPTION

In the specification, when one component (or area, layer, part, or the like) is referred to as being “on”, “connected to”, or “coupled to” another component, it should be understood that the former may be directly on, connected to, or coupled to the latter, and also may be on, connected to, or coupled to the latter via a third intervening component.

Like reference numerals refer to like components. Also, in drawings, the thickness, ratio, and dimension of components are exaggerated for effectiveness of description of technical contents. The term “and/or” includes one or more combinations of the associated listed items.

The terms “first”, “second”, etc. are used to describe various components, but the components are not limited by the terms. The terms are used solely for the purpose of distinguishing one element, component, region, layer, or portion from another element, component, region, layer, or portion. For example, without departing from the scope of the present disclosure, a first element, a first component, a first region, a first layer, or a first portion may be termed a second element, a second component, a second region, a second layer, or a second portion, and similarly, a second element, a second component, a second region, a second layer, or a second portion may also be termed a first element, a first component, a first region, a first layer, or a first portion. Singular expressions may include plural expressions unless the context clearly dictates otherwise.

Also, the terms “under”, “beneath”, “on”, “above” are used to describe a relationship between components illustrated in a drawing. The terms are relative and are described with reference to a direction indicated in the drawing.

It will be understood that the terms “include”, “comprise”, “have”, etc. specify the presence of features, numbers, steps, operations, elements, or components, described in the specification, or a combination thereof, not precluding the presence or additional possibility of one or more other features, numbers, steps, operations, elements, components, or a combination thereof.

Unless defined otherwise, all terms (including technical and scientific terms) used herein have the same meaning as commonly understood by one of ordinary skill in the art to which this disclosure belongs. In addition, terms such as terms defined in commonly used dictionaries should be interpreted as having a meaning consistent with the meaning in the context of the related technology, and should not be interpreted as an ideal or excessively formal meaning unless explicitly defined in the present disclosure.

Hereinafter, aspects of some embodiments of the present disclosure will be described in more detail with reference to accompanying drawings.

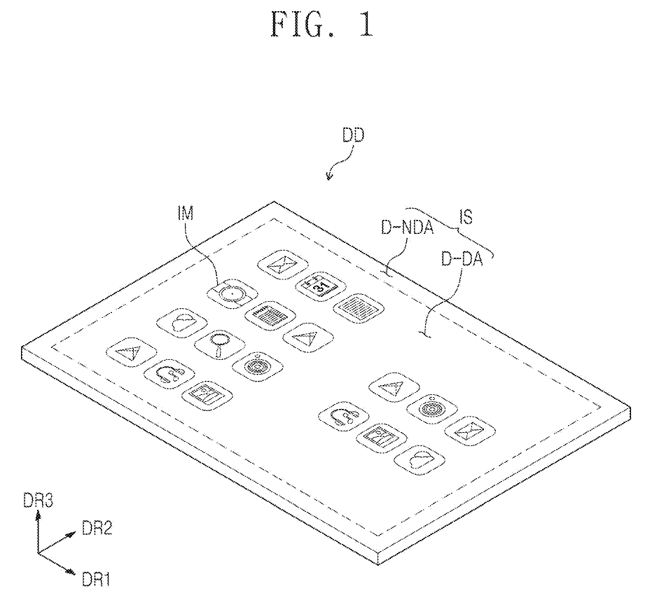

FIG. 1 is a perspective view illustrating an electronic device DD, according to some embodiments of the present disclosure.

The electronic device DD may be a display device that is activated by an electrical signal and displays an image IM. The electronic device DD may include various embodiments that provide the image IM to a user. For example, the electronic device DD may be employed in large devices such as televisions, outdoor billboards, etc., as well as small and medium-sized devices such as monitors, mobile phones, tablets, navigation systems, game consoles, etc. The embodiments of the electronic device DD described above are examples and are not limited to any one of them unless they deviate from the concept of the present disclosure.

Referring to FIG. 1, the electronic device DD may have a rectangular shape having long sides extending in a first direction DR1 on a plane (e.g., in a plan view) and short sides extending in a second direction DR2 on the plane (e.g., in the plan view). However, the electronic device DD is not limited thereto, and may have various shapes such as a circular shape or a polygonal shape that is not a rectangular shape on the plane (e.g., in the plan view).

The electronic device DD may display the image IM in a third direction DR3 through a display surface IS parallel to a plane defined by the first direction DR1 and the second direction DR2. The third direction DR3 may be parallel to a normal direction of the display surface IS. The display surface IS on which the image IM is displayed may correspond to the front surface of the electronic device DD. The image IM may include a still image as well as a moving image. FIG. 1 illustrates icon images as an example of the image IM.

FIG. 1 illustrates the electronic device DD having the display surface IS of a flat type as an example. However, without being limited thereto, the display surface IS of the electronic device DD may further include a curved surface bent from a flat surface.

In the present embodiments, the front surface (or upper surface) and the rear surface (or lower surface) of the members forming the electronic device DD may be defined based on the third direction DR3. The front surface and the back surface may be opposed to each other in the third direction DR3, and the normal directions of each of the front surface and the back surface may be parallel to the third direction DR3. The distance between the front surface and the back surface defined along the third direction DR3 may correspond to the thickness of the member.

In this specification, the phrases “on a plane” and “in a plan view” may be defined as a state viewed from the third direction DR3. In this specification, “in cross section” may be defined as a state viewed from the first direction DR1 or the second direction DR2. However, the directions indicated by the first to third directions DR1, DR2, and DR3 are relative concepts and may be converted into other directions.

The electronic device DD may have a flexible structure. The “flexible” means a characteristic that may be bent, and may include everything from a completely foldable structure to a structure that may be bent to a level of several nanometers. For example, the flexible electronic device DD may include a curved device, a rollable device, a slidable device, or a foldable device. However, the electronic device DD may have a rigid structure, without being limited thereto.

The display surface IS of the electronic device DD may include a display portion D-DA and a non-display portion D-NDA. The display portion D-DA may be a portion within the front surface of the electronic device DD in which the image IM is displayed, and a user may view the image IM through the display portion D-DA. Although FIG. 1 illustrates the display portion D-DA having a rectangular shape on a plane (e.g., in a plan view) as an example, the shape of the display portion D-DA may be variously changed depending on the design of the electronic device DD.

The non-display portion D-NDA may be a portion within the front surface of the electronic device DD in which the image IM is not displayed. The non-display portion D-NDA may be a portion having a color (e.g., a set or predetermined color) and blocking light. The non-display portion D-NDA may be adjacent to the display portion D-DA. For example, the non-display portion D-NDA may be located on the outside of the display portion D-DA and may surround the display portion D-DA. However, this is merely an example, and the non-display portion D-NDA may be adjacent to only one side of the display portion D-DA, or located in a side surface other than the front surface of the electronic device DD, but embodiments of the present disclosure are not limited thereto, and the non-display portion D-NDA may be omitted.

The electronic device DD may sense an external input applied from the outside. The external input may take various forms, such as pressure, temperature, light, etc. provided from the outside. The external input may include an input (e.g., contact by the user’s hand or a pen) that contacts the electronic device DD, as well as an input (e.g., hovering) that is applied in proximity to the electronic device DD.

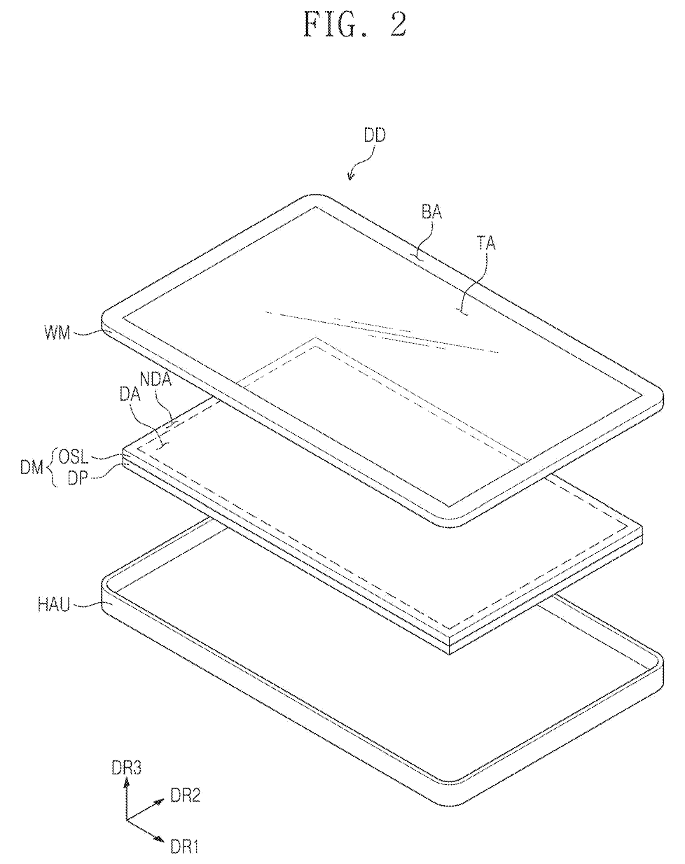

FIG. 2 is an exploded perspective view of the electronic device DD, according to some embodiments of the present disclosure.

Referring to FIG. 2, the electronic device DD may include a window WM, a display module DM, and a housing HAU.

The window WM and the housing HAU may be combined to form an exterior of the electronic device DD and may provide an internal space capable of accommodating components of the electronic device DD, such as the display module DM.

The window WM may be located on the display module DM. The window WM may protect the display module DM from external impact. A front surface of the window WM may correspond to the display surface IS (refer to FIG. 1) of the electronic device DD described above. The front surface of the window WM may include a transmissive area TA and a bezel area BA.

The transmissive area TA of the window WM may be an optically transparent area. The window WM may transmit the image provided by the display module DM through the transmissive area TA, and the user may view the image. The transmissive area TA may correspond to the display portion D-DA (refer to FIG. 1) of the electronic device DD described above.

The window WM may include an optically transparent insulating material. For example, the window WM may include glass, sapphire, or plastic. The window WM may have a single-layer or a multi-layer structure. The window WM may further include a functional layer, such as an anti-fingerprint layer, a phase control layer, and/or a hard coating layer, located on an optically transparent substrate.

The bezel area BA of the window WM may be provided as an area on which a material having a color (e.g., a set or predetermined color) is deposited, coated, or printed on a transparent substrate. The bezel area BA of the window WM may prevent or reduce visibility of one component of the display module DM overlapping the bezel area BA from the outside. The bezel area BA may correspond to the non-display portion D-NDA (refer to FIG. 1) of the electronic device DD described above.

The display module DM may be located between the window WM and the housing HAU. The display module DM may display an image according to an electrical

signal. The display module DM may include a display area DA and a non-display area NDA adjacent to the display area DA.

The display area DA may be an area that is activated by an electrical signal and outputs the image. The display area DA of the display module DM may overlap the transmissive area TA of the window WM. Meanwhile, in the present specification, “areas/portions and areas/portions overlap each other” is not limited to having the same area and/or the same shape. The image output from the display area DA may be visually recognized from the outside through the transmissive area TA.

The non-display area NDA may be adjacent to the display area DA. For example, the non-display area NDA may surround the display area DA. However, embodiments of the present disclosure are not limited thereto, and the non-display area NDA may be defined in various shapes. The non-display area NDA may be an area where driving circuits for driving elements that are placed in the display area DA, signal lines for providing electrical signals to the elements, and pads are placed. The non-display area NDA of the display module DM may overlap the bezel area BA of the window WM, and visibility of the components arranged in the non-display area NDA from the outside by the bezel area BA may be prevented or reduced.

The housing HAU may be located under the display module DM to accommodate the display module DM. The housing HAU may absorb impact applied to the display module DM from the outside and protect the display module DM by preventing or reducing contaminants or foreign substances/moisture, etc., penetrating into the display module DM. According to some embodiments, the housing HAU may be provided in a form in which a plurality of accommodation members are combined.

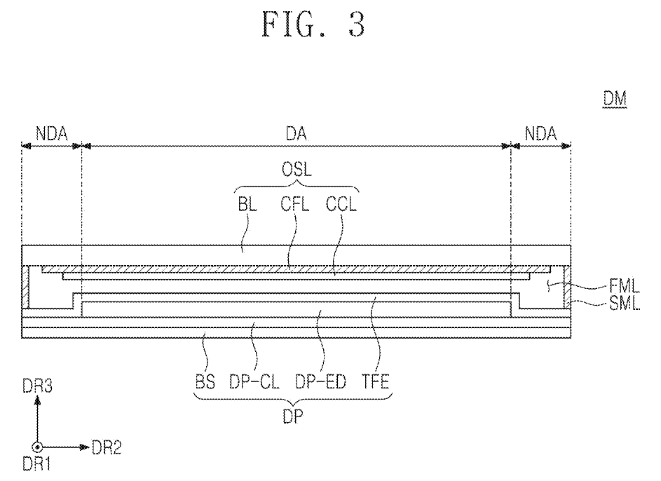

FIG. 3 is a cross-sectional view of the display module DM, according to some embodiments of the present disclosure.

Referring to FIGS. 2 and 3, the display module DM may include a display panel DP and an optical control layer OSL located on the display panel DP.

The display panel DP according to some embodiments may be a light emitting display panel, but embodiments of the present disclosure are not particularly limited thereto. For example, the display panel DP may be an organic light emitting display panel, an inorganic light emitting display panel, or a quantum dot light emitting display panel. A light emitting layer of the organic light emitting display panel may include an organic light emitting material, and a light emitting layer of the inorganic light emitting display panel may include an inorganic light emitting material. A light emitting layer of the quantum dot light emitting display panel may include quantum dots, quantum rods, etc. Hereinafter, it is described that the display panel DP is an organic light emitting display panel.

The display panel DP may include a base substrate BS, a circuit layer DP-CL, a display element layer DP-ED, and an encapsulation layer TFE.

The base substrate BS may provide a base surface on which the circuit layer DP-CL is arranged. The base substrate BS may be a rigid substrate or a flexible substrate. The base substrate BS may include a glass or a synthetic resin layer. The synthetic resin layer may include a thermosetting resin material. For example, the synthetic resin layer may be a polyimide-based resin layer, and the material thereof is not specifically limited. In addition, the base substrate BS may include a glass substrate, a metal substrate, or an organic/inorganic composite material substrate.

The circuit layer DP-CL may be arranged on the base substrate BS. The circuit layer DP-CL may include driving elements such as transistors, signal lines, and pads. The circuit layer DP-CL may be arranged on the base substrate BS. The circuit layer DP-CL may include an insulating layer, a semiconductor pattern, a conductive pattern, and a signal line. The insulating layer, the semiconductor layer, and the conductive layer may be formed on the base substrate BS by a coating, deposition, or the like, and the insulating layer, the semiconductor layer, and the conductive layer may be selectively patterned through multiple photolithography processes. Accordingly, a semiconductor pattern, a conductive pattern, and a signal line may be formed on the circuit layer DP-CL. The circuit layer DP-CL may include a transistor, a buffer layer, and a plurality of insulating layers.

The display element layer DP-ED may include light emitting elements arranged to overlap the display area DA. The light emitting elements of the display element layer DP-ED may be electrically connected to the driving elements of the circuit layer DP-CL and may output light through the display area DA according to a signal of the driving element.

The encapsulation layer TFE may be located on the display element layer DP-ED to seal the light emitting elements. The encapsulation layer TFE may include thin films for relatively improving the optical efficiency of the light emitting elements or protecting the light emitting elements.

The optical control layer OSL may be located on the display panel DP. The optical control layer OSL may be manufactured through a manufacturing process separate from the manufacturing process of the display panel DP and may be combined on the display panel DP. For example, the optical control layer OSL may be provided on the display panel DP and then combined with the display panel DP through a bonding process using a sealing member SML.

However, embodiments of the present disclosure are limited thereto, and the optical control layer OSL may be directly located on the display panel DP. In the present specification, the term “directly located” may be used to refer to a state in which a separate adhesive layer or a separate adhesive member is not located and is formed through a continuous process. For example, the term “the optical control layer OSL is directly located on the display panel DP” may refer to a state in which the optical control layer OSL is formed through the continuous process on a base surface provided by the display panel DP after the display panel DP is formed.

The optical control layer OSL may convert the wavelength of light provided by the display panel DP, for example, source light, or may selectively transmit the source light. In addition, the optical control layer OSL may control the optical properties of external light incident from the outside of the electronic device DD to reduce an external light reflectance.

The optical control layer OSL may include a base layer BL, a color filter layer CFL, and a light conversion layer CCL. The base layer BL may be arranged facing the base substrate BS of the display panel DP, and the color filter layer CFL and the light conversion layer CCL located on the base layer BL may be positioned between the display panel DP and the base layer BL.

The light conversion layer CCL may convert the optical properties of the source light provided by the display panel DP. For example, the light conversion layer CCL may include a quantum dot that converts the wavelength of the source light provided by the display panel DP. The source light passing through the quantum dot included in the light conversion layer CCL may be output as a light having a color different from the color of the source light. The light conversion layer CCL may further include a transmission portion that transmits the source light provided by the display panel DP.

The color filter layer CFL may include color filters each having a color (e.g., a set or predetermined color). The color filters may transmit or absorb the light passing through the light conversion layer CCL depending on the colors of the color filters. The color filter layer CFL may absorb light that is not converted by the light conversion layer CCL to prevent or reduce degradation of the color purity or color reproducibility of the electronic device DD.

The color filters of the color filter layer CFL may absorb external light incident from the outside of the electronic device DD depending on the colors of the color filters. The color filters may filter external light into the same color as the color of the light output through the pixels, thereby reducing the external light reflectance.

The sealing member SML is located in the non-display area NDA, which is an outer part of the display module DM, to prevent or reduce contaminants or foreign substances such as oxygen or moisture flowing into the display module DM from the outside. The sealing member SML may be formed from a sealant containing a curable resin.

The display module DM may further include a filling layer FML located between the display panel DP and the optical control layer OSL. The filling layer FML may fill a space between the display panel DP and the optical control layer OSL. The filling layer FML may function as a buffer between the display panel DP and the optical control layer OSL. The filling layer FML may absorb impact and increase the strength of the display module DM.

The filling layer FML may include a polymer resin. For example, the filling layer FML may include an acrylic resin or an epoxy resin. However, according to some embodiments, because the optical control layer OSL is directly located on the display panel DP, the filling layer FML and the sealing member SML may be omitted. In addition, in embodiments where the optical control layer OSL is directly located on the display panel DP, because the display panel DP provides the base surface, the base layer BL of the optical control layer OSL may be omitted.

Meanwhile, the electronic device DD may further include an input detection module. The input detection module may obtain coordinate information of an external input applied from outside the electronic device DD. The input detection module may be driven in various ways, such as a capacitive method, a resistive method, an infrared method, or a pressure method, and is not limited to anyone.

According to some embodiments, the input detection module may be placed on the display module DM. The input detection module may be directly located on the display module DM through a continuous process, or may be attached to the display module DM through a separate adhesive layer, without being limited thereto. In addition, the input detection module may be located between the components of the display module DM. For example, the input detection module may be located between the display panel DP and the optical control layer OSL.

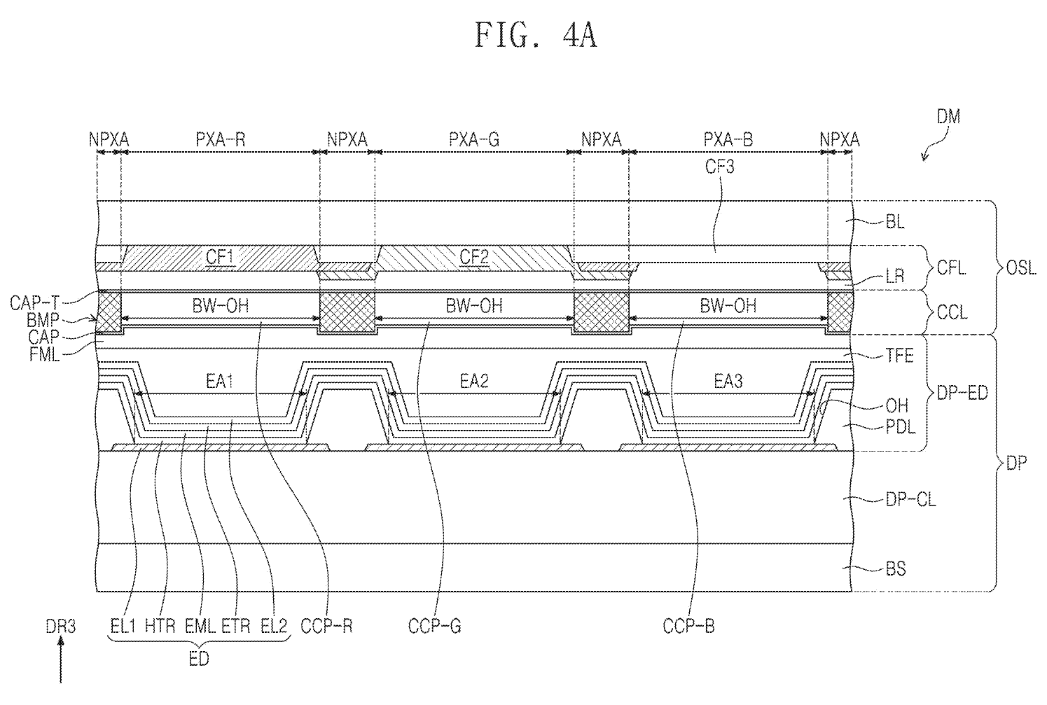

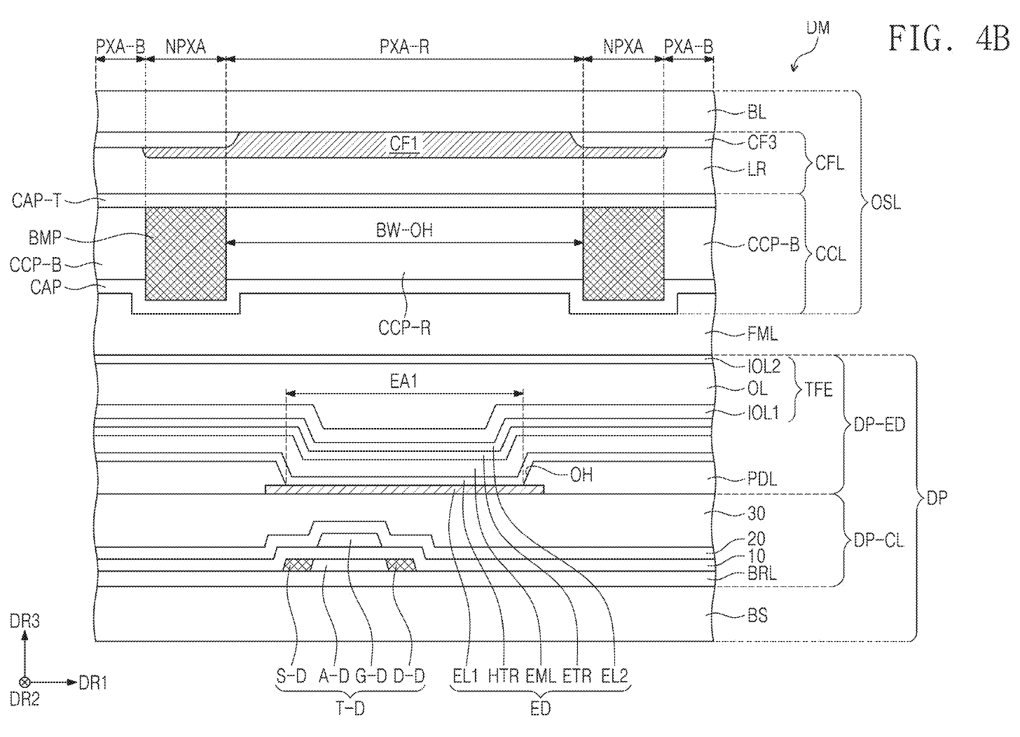

FIG. 4A is a cross-sectional view of a display module, according to some embodiments of the present disclosure, and FIG. 4B is an enlarged cross-sectional view of a portion of a display module, according to some embodiments of the present disclosure.

Referring to FIGS. 4A and 4B, the display panel DP according to some embodiments may include the base substrate BS, the circuit layer DP-CL located on the base substrate BS, and the display element layer DP-ED located on the circuit layer DP-CL.

The circuit layer DP-CL may be arranged on the base substrate BS. The circuit layer DP-CL may include a transistor T-D as a circuit element. FIG. 4B illustrates the single transistor T-D and the arrangement of an active region A-D, a source region S-D, a drain region D-D, and a gate region G-D consistuting the transistor T-D as an example. The active region A-D, the source region S-D, and the drain region D-D may be regions differentiated according to the doping concentration or conductivity of the semiconductor pattern.

The circuit layer DP-CL may include a lower buffer layer BRL, a first insulating layer 10, a second insulating layer 20, and a third insulating layer 30 located on the base substrate BS. For example, the lower buffer layer BRL, the first insulating layer 10, and the second insulating layer 20 may be inorganic layers, and the third insulating layer 30 may be an organic layer.

The display element layer DP-ED may include a light emitting element ED as a display element. The light emitting element ED may generate the source light described above. The light emitting element ED includes a first electrode EL1, a second electrode EL2, and an emission layer EML located between the first electrode EL1 and the second electrode EL2. According to some embodiments, the display element layer DP-ED may include an organic light-emitting diode as the light emitting element. According to some embodiments of the present disclosure, the light emitting element may include a quantum dot light-emitting diode. That is, the emission layer EML included in the light emitting element ED may include an organic light-emitting material as the light-emitting material, or the emission layer EML may include quantum dots as the light-emitting material. Alternatively, the display element layer DP-ED according to some embodiments may include an ultra-small light emitting element, as the light emitting element. The ultra-small light emitting element may include, for example, a micro-LED element and/or a nano-LED element. The ultra-small light emitting element may be a light emitting element having a micro-scale size or a nano-scale size and including an active layer located between a plurality of semiconductor layers.

The first electrode EL1 is located on the third insulating layer 30. The first electrode EL1 may be referred to as an anode or a cathode. The first electrode EL1 may be directly or indirectly connected to the transistor T-D. The connection structure between the first electrode EL1 and the transistor T-D is not illustrated in FIG. 4B.

The display element layer DP-ED includes a pixel defining film PDL. For example, the pixel defining film PDL may be an organic layer. Light-emitting apertures OH are defined in the pixel defining film PDL. Each of the light-emitting apertures OH of the pixel defining film PDL exposes at least a portion of the first electrode EL1. According to some embodiments, first to third light-emitting areas EA1, EA2, and EA3 may be defined by the light-emitting apertures OH. The first emission area EA1, the second emission area EA2, and the third emission area EA3 may correspond to a first pixel area PXA-R, a second pixel area PXA-G, and a third pixel area PXA-B, respectively. A non-pixel area NPXA may be defined between the first to third pixel areas PXA-R, PXA-G, and PXA-B.

The first electrode EL1 may be arranged to correspond to the first to third pixel areas PXA-R, PXA-G, and PXA-B and may not be arranged in the non-pixel area NPXA.

A hole control layer HTR may be arranged between the first electrode EL1 and the emission layer EML. The hole control layer HTR may include at least one of a hole injection layer, a hole transport layer, or an electron blocking layer. The hole control layer HTR may be arranged as a common layer to overlap the first to third light-emitting areas EA1, EA2, and EA3 and the non-pixel area NPXA. However, the embodiments according to the present disclosure are not limited thereto, and the hole control layer HTR may be patterned so as to be arranged separately corresponding to each of the first to third light-emitting areas EA1, EA2, and EA3.

The emission layer EML is located on the hole control layer HTR. The emission layer EML may have a single layer made of a single material, a single layer made of multiple different materials, or a multilayer structure including multiple layers made of multiple different materials. The emission layer EML may include a fluorescent material or a phosphorescent material. According to some embodiments, the light emitting element may include an organic light-emitting material, a metal-organic complex, or a quantum dot as a light-emitting material. Meanwhile, while FIGS. 4A and 4B illustrate the light emitting element ED including the single emission layer EML, according to some embodiments, the light emitting element ED may include multiple light-emitting stacks, each of which includes at least one emission layer.

According to some embodiments, the emission layer EML may be provided as a common layer to overlap the first to third light-emitting areas EA1, EA2, and EA3 and the non-pixel area NPXA. According to some embodiments, the emission layer EML may emit blue light. The emission layer EML may overlap the hole control layer HTR. However, the embodiments according to the present disclosure are not limited thereto, and according to some embodiments, the emission layer EML may be located within the light-emitting apertures OH. In detail, the emission layer EML may be formed separately to correspond to each of the first to third light-emitting areas EA1, EA2, and EA3 defined by the pixel defining film PDL. The emission layers EML, which are formed separately to correspond to the first to third light-emitting areas EA1, EA2, and EA3, may all emit blue light or may emit light of different wavelength ranges.

An electron control layer ETR is located between the emission layer EML and the second electrode EL2. The electron control layer ETR may include at least one of an electron transport layer, an electron injection layer, or a hole blocking layer. The electron control layer ETR may be arranged as a common layer to overlap the first to third light-emitting areas EA1, EA2, and EA3 and the non-pixel area NPXA. However, the embodiments according to the present disclosure are not limited thereto, and the electron control layer ETR may be patterned so as to be arranged separately corresponding to each of the first to third light-emitting areas EA1, EA2, and EA3.

The second electrode EL2 is located on the electron control layer ETR. The second electrode EL2 may be referred to as an anode or a cathode. When the first electrode EL1 is the anode, the second electrode EL2 may be the cathode, and when the first electrode EL1 is the cathode, the second electrode EL2 may be the anode. The second electrode EL2 may be arranged as a common layer to overlap the first to third light-emitting areas EA1, EA2, and EA3 and the non-pixel area NPXA.

The display element layer DP-ED may include the encapsulation layer TFE that protects the second electrode EL2. The encapsulation layer TFE may include an organic material or an inorganic material. The encapsulation layer TFE may have a multilayer structure with alternating inorganic and organic layers. According to some embodiments, the encapsulation layer TFE may include a first inorganic layer IOL1, an organic layer OL, and a second inorganic layer IOL2. The first and second inorganic layers IOL1 and IOL2 protect the light emitting element ED from external moisture, and the organic layer OL prevents or reduces denting defects in the light emitting element ED caused by foreign substances introduced during the manufacturing process. According to some embodiments, the display panel DP may further include a refractive index control layer on top of the encapsulation layer TFE to relatively improve light output efficiency.

The optical control layer OSL is located on the encapsulation layer TFE. The optical control layer OSL may include the light conversion layer CCL, the color filter layer CFL, and the base layer BL. In this specification, the optical control layer OSL may be referred to as an upper panel or an optical substrate.

The light conversion layer CCL may be located on the display element layer DP-ED including the light emitting element ED. The light conversion layer CCL includes a bank BMP, light conversion patterns CCP-R, CCP-G, and CCP-B, and a barrier layer CAP.

The bank BMP may include a black coloring agent for light blocking. The bank BMP may include a black dye or a black pigment mixed into a base resin. According to some embodiments, The black coloring agent may include carbon black, a metal such as chromium, or an oxide thereof.

The bank BMP includes bank apertures BW-OH corresponding to the light-emitting apertures OH. In a plain view, the bank apertures BW-OH overlap with the light-emitting apertures OH and may have a larger area than the light-emitting apertures OH. That is, each of the bank apertures BW-OH may have a larger area than the first to third light-emitting areas EA1, EA2, and EA3 defined by the light-emitting apertures OH.

The light conversion patterns CCP-R, CCP-G, and CCP-B are arranged inside the bank apertures BW-OH. The light conversion patterns CCP-R, CCP-G, and CCP-B may change the optical properties of the source light.

The light conversion patterns CCP-R, CCP-G, and CCP-B may include quantum dots that modify the optical properties of the source light. Each of the light conversion patterns CCP-R, CCP-G, and CCP-B may include the quantum dots that convert the source light into light of a different wavelength. The quantum dot included in the first light conversion pattern CCP-R overlapping the first pixel area PXA-R may be a red quantum dot that converts blue light, which is the source light, into red light. The quantum dot included in the second light conversion pattern CCP-G overlapping the second pixel area PXA-G may be a green quantum dot that converts blue light, which is the source light, into green light. The quantum dot included in the third light conversion pattern CCP-B overlapping the third pixel area PXA-B may be blue quantum dots that converts blue light, which is the source light, into blue light. Each of the light conversion patterns CCP-R, CCP-G, and CCP-B may further include a scatterer.

According to some embodiments, the light conversion patterns CCP-R, CCP-G, and CCP-B may be formed using an inkjet process. A liquid composition is provided within the bank aperture BW-OH.

The light conversion layer CCL further includes a barrier layer CAP covering one surface (or referred to as a lower surface or a first surface) of the light conversion patterns CCP-R, CCP-G, and CCP-B. The barrier layer CAP may serve to prevent or reduce the penetration of contaminants such as moisture and/or oxygen (hereinafter referred to as “moisture/oxygen”). The barrier layer CAP may block the light conversion patterns CCP-R, CCP-G, and CCP-B from being exposed to moisture/oxygen. The barrier layer CAP may also protect the light conversion patterns CCP-R, CCP-G, and CCP-B from external impact.

According to some embodiments, the light conversion layer CCL may further include an additional barrier layer CAP-T that covers the other surface (also referred to as an upper surface or a second surface) of the light conversion patterns CCP-R, CCP-G, and CCP-B. The barrier layer CAP and the additional barrier layer CAP-T may cover not only the light conversion patterns CCP-R, CCP-G, and CCP-B but also the bank BMP.

The barrier layer CAP and the additional barrier layer CAP-T may be formed of an inorganic material. Each of the barrier layer CAP and the additional barrier layer CAP-T may further include an organic film and may be composed of multiple layers.

The color filter layer CFL is located on the light conversion layer CCL. The color filter layer CFL includes a plurality of color filters CF1, CF2, and CF3. Each of the color filters CF1, CF2, and CF3 transmits light within a specific wavelength range and blocks light outside the corresponding wavelength range. The first color filter CF1 of the first pixel area PXA-R may transmit red light and may block green light and blue light, and the second color filter CF2 of the second pixel area PXA-G may transmit green light and may block red light and blue light. The third color filter CF3 of the third pixel area PXA-B may transmit blue light and may block red light and green light. Each of the color filters CF1, CF2, and CF3 may include a base resin and a dye and/or pigment dispersed in the base resin.

The color filter layer CFL may further include a low-refractive-index layer LR. The low-refractive-index layer LR may be located between the light conversion layer CCL and the color filters CF1, CF2, and CF3. The low-refractive-index layer LR may be arranged over the light conversion layer CCL to block the light conversion patterns CCP-R, CCP-G, and CCP-B from being exposed to moisture/oxygen. Furthermore, the low-refractive-index layer LR may function as an optical functional layer, such as increasing light extraction efficiency between the light conversion layer CCL and the color filters CF1, CF2, and CF3 or preventing or reducing reflected light entering the light conversion layer CCL. The low-refractive-index layer LR may have a lower refractive index than adjacent layers. The low-refractive-index layer LR may include at least one inorganic layer.

The filling layer FML may be located between the display panel DP and the optical control layer OSL. According to some embodiments, the filling layer FML may be filled between the display element layer DP-ED and the light conversion layer CCL. The filling layer FML may function as a buffer between the display element layer DP-ED and the light conversion layer CCL. According to some embodiments, the filling layer FML may perform a shock absorption function, etc., and may increase the strength of the display module DM.

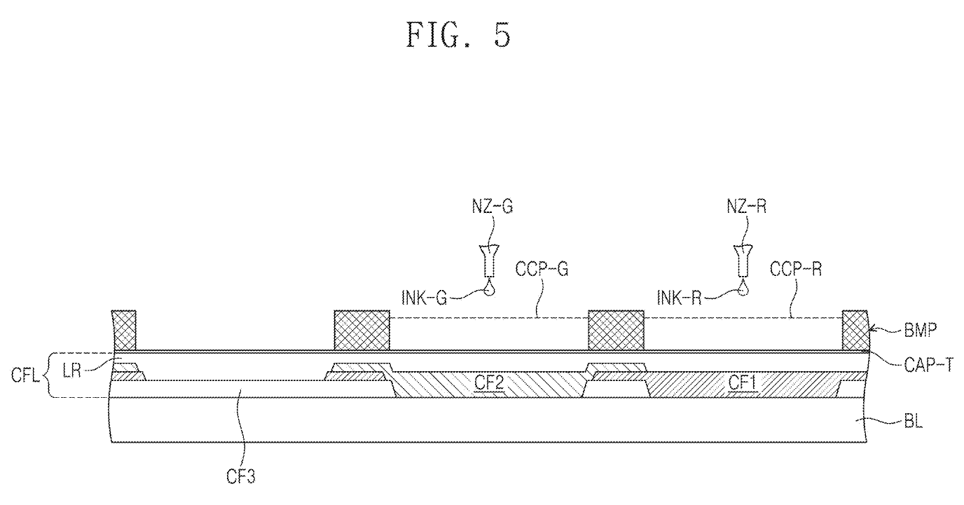

FIG. 5 is a cross-sectional view illustrating one step of a method for manufacturing a display module, according to some embodiments of the present disclosure.

Referring to FIG. 5, the bank apertures BW-OH corresponding to the first pixel area PXA-R, the second pixel area PXA-G, and the third pixel area PXA-B may be formed between the banks BMP, and the plurality of light conversion patterns CCP-R, CCP-G, and CCP-B (refer to FIG. 4A) may be formed within the bank apertures BW-OH.

A first ink INK-R may be provided by a first nozzle NZ-R to the inside of the bank apertures BW-OH overlapping the first pixel area PXA-R, and a second ink INK-G may be provided by a second nozzle NZ-G to the inside of the bank apertures BW-OH overlapping the second pixel area PXA-G. Each of the bank apertures BW-OH may be defined as a printing area where inks are printed.

The first ink INK-R and the second ink INK-G may each be a composition including quantum dots and scatterers. The first ink INK-R may include red quantum dots and scatterers, and the second ink INK-G may include green quantum dots and scatterers. According to some embodiments, a method for manufacturing the display module DM may include performing a thermal curing process or a photocuring process on the compositions provided in the bank apertures BW-OH overlapping the first pixel area PXA-R and the second pixel area PXA-G, thereby forming the first light conversion pattern CCP-R and the second light conversion pattern CCP-G.

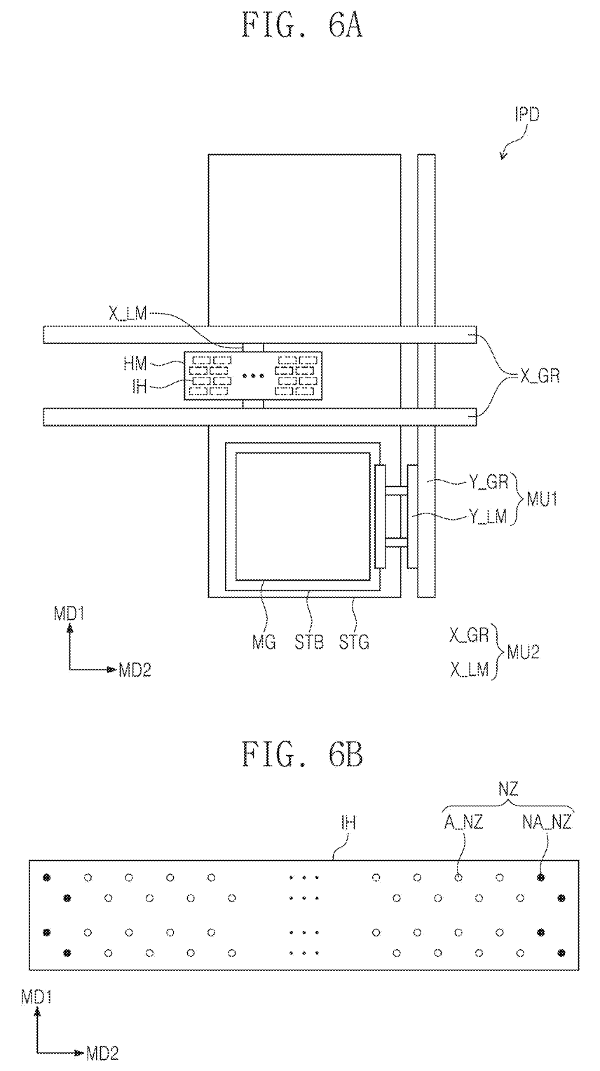

The first ink INK-R and the second ink INK-G may each be provided using an inkjet process. The first nozzle NZ-R and the second nozzle NZ-G, which provide the first ink INK-R and the second ink INK-G, respectively, may be included in an inkjet printing apparatus IPD (refer to FIG. 6), which will be described later.

While FIG. 5 illustrates that the light conversion patterns CCP-R and CCP-G are formed using the inkjet process by way of example, the present disclosure is not limited thereto, and the color filters CF1, CF2, and CF3 (refer to FIG. 4A) or the emission layer EML (refer to FIG. 4A) may also be formed using the inkjet process. A pattern or layer formed using the inkjet process may be referred to as a pattern layer.

The display module DM may be manufactured using an inkjet process using the inkjet printing apparatus IPD.

FIG. 6A is a plan view illustrating an inkjet printing apparatus, according to some embodiments of the present disclosure. FIG. 6B is a plan view illustrating an example of an inkjet head illustrated in FIG. 6A.

Referring to FIGS. 6A and 6B, the inkjet printing apparatus IPD may include a stage STG, a support table STB, a head module HM, a first moving unit (or first mover) MU1, and a second moving unit (or second mover) MU2.

The support table STB is located on the stage STG and may move in a first-axis direction MD1 on the stage STG. A target substrate MG may be located on the support table STB. A suction hole may be defined in the support table STB. The target substrate MG may be fixed to the stage STG by adsorption method through the suction hole of the support table STB. Therefore, when the support table STB moves, the target substrate MG fixed to the support table STB may move along with the support table STB.

The first moving unit MU1 may be located at one side of the stage STG. The first moving unit MU1 may include a first-axis guide rail Y_GR and a first-axis linear motor Y_LM connected to the first-axis guide rail Y_GR. The first-axis linear motor Y_LM may be coupled to the support table STB. The first-axis linear motor Y_LM may move the support table STB in the first-axis direction MD1. An encoder may be installed in the first-axis linear motor Y_LM to measure the position of the support table STB (i.e., the position of the target substrate MG).

The head module HM may be located on the support table STB to face the target substrate MG. When the target substrate MG moves in the first-axis direction MD1, the head module HM may move in a second-axis direction MD2. The second-axis direction MD2 may be orthogonal (or substantially orthogonal) to the first-axis direction MD1.

The head module HM may eject ink onto a printing position (or a printing area) of the target substrate MG while moving in the second-axis direction MD2 when the target substrate MG moves in the first-axis direction MD1. The head module HM may include a plurality of inkjet heads IH. A plurality of nozzles NZ may be provided on one side of each inkjet head IH to eject ink. In the present disclosure, the nozzles NZ may be provided on a lower surface of the inkjet head IH. The nozzles NZ may be arranged in the first-axis direction MD1 and the second-axis direction MD2.

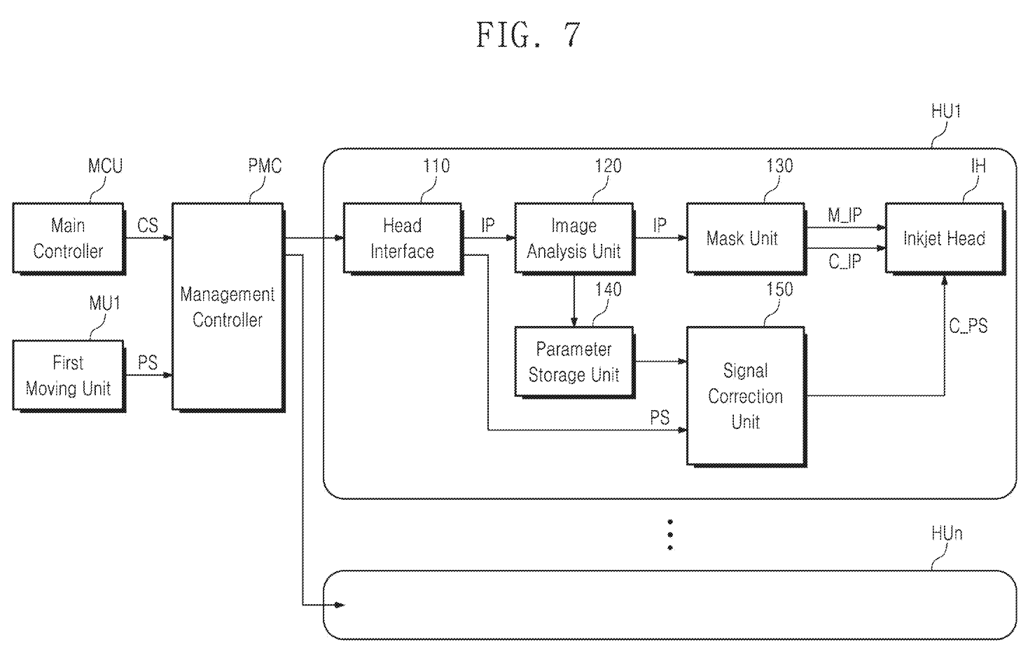

FIG. 6B illustrates a structure in which the nozzles NZ are arranged in four rows, but the number of rows is not limited thereto. The nozzles NZ may include active nozzles A_NZ that eject ink and inactive nozzles NA_NZ that do not eject ink. The inactive nozzles NA_NZ may be located adjacent to both ends of the inkjet head IH. The inactive nozzles NA_NZ may be switched to an inactive state that does not eject ink according to the masking operation of a mask unit (or mask component) 130 illustrated in FIG. 7, and may be in an active state that ejects ink when the masking operation is not performed.

The head module HM may further include an ink supply chamber that supplies ink to the inkjet head IH.

The second moving unit MU2 may be coupled to the head module HM and may move the head module HM in the second-axis direction MD2. The second moving unit MU2 may include a second-axis guide rail X_GR and a second-axis linear motor X_LM connected to the second-axis guide rail X_GR. The second-axis linear motor X_LM may be coupled to the head module HM. The second-axis linear motor X_LM may move the head module HM in the second-axis direction MD2.

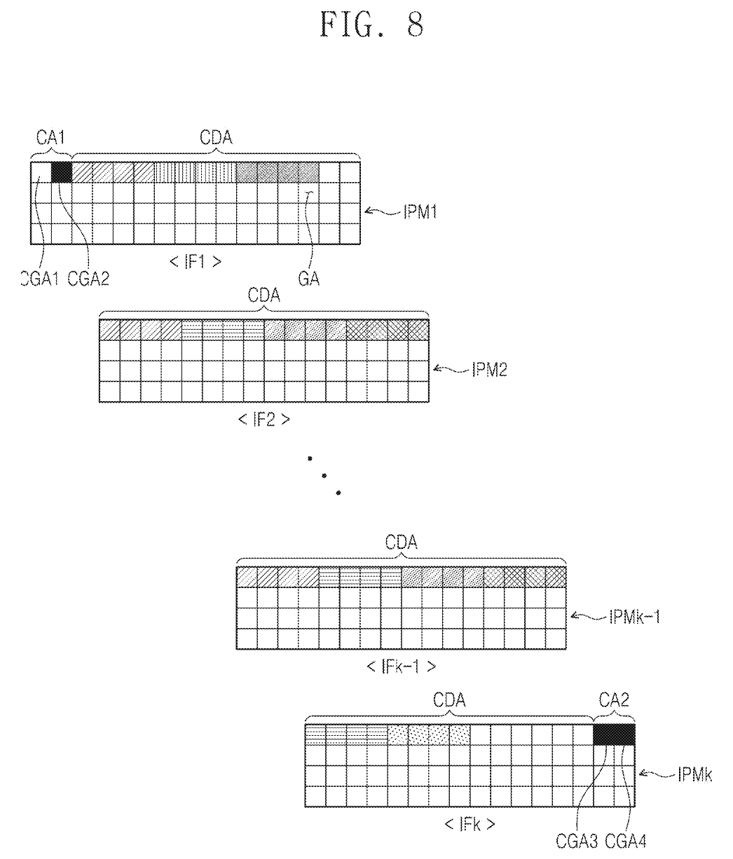

FIG. 7 is a block diagram of an inkjet printing apparatus, according to some embodiments of the present disclosure. FIG. 8 is a plan view illustrating first to k-th print images, which are images of print image data, according to some embodiments of the present disclosure.

Referring to FIGS. 7 and 8, the inkjet printing apparatus IPD may include a management controller PMC and a plurality of head units (or head components) HU1 to HUn. The management controller PMC may receive a control signal CS from a main controller MCU and a position signal PS from the first moving unit MU1. For example, the position signal PS may be a signal provided from the encoder of the first-axis linear motor Y_LM (refer to FIG. 6).

The management controller PMC may manage and control the overall operation of the inkjet printing apparatus IPD in response to the control signal CS received from the main controller MCU. The management controller PMC may be connected to the plurality of head units HU1 to HUn and may control the operations of the plurality of head units HU1 to HUn. For example, the management controller PMC may provide print image data IP and the position signal PS to each of the head units HU1 to HUn. The print image data IP may include information about the amount of ink ejected from each nozzle among the plurality of nozzles provided in each of the head units HU1 to HUn. Furthermore, according to some embodiments of the present disclosure, the print image data IP may include information about a correction amount used to correct the position signal PS.

Because each of the plurality of head units HU1 to HUn has the same configuration, only the configuration of the first head unit (or first head component) HU1 is illustrated in FIG. 7 as an example.

The first head unit HU1 may include a head interface 110, an image analysis unit 120, the mask unit 130, a parameter storage unit (or parameter storage or parameter memory or parameter storage component) 140, a signal correction unit (or signal corrector) 150, and the inkjet head IH.

The first head unit HU1 may receive the print image data IP and the position signal PS from the management controller PMC through the head interface 110. The head interface 110 may provide the print image data IP to the image analysis unit 120 and may provide the position signal PS to the signal correction unit 150.

The image analysis unit (or image analyzer or image analysis component or image analysis circuit) 120 extracts a first command from the print image data IP and determines whether to initiate a compensation setting operation based on the first command.

As illustrated in FIG. 8, a print image I_IP, which is an image of the print image data IP (refer to FIG. 7), may include a plurality of grayscale areas GA. The plurality of grayscale areas GA may each correspond to the plurality of nozzles NZ (refer to FIG. 6B) arranged in the inkjet head IH. While FIG. 8 illustrates a structure in which the plurality of grayscale areas GA are arranged in a 4X16 array, the present disclosure is not limited thereto. That is, the number and shape of the plurality of grayscale areas GA included in the print image I_IP may vary. The first head unit HU1 may receive the print image data corresponding to a single print image I_IP in units of print frame sections.

FIG. 8 illustrates print images from a first print frame section IF1 to a k-th print frame section IFk. Here, “k” may be an integer greater than or equal to 1. The print image obtained by imaging the print image data IP received during the first print frame section IF1 is referred to as a first print image IPM1, and the print image obtained by imaging the print image data IP received during the second print frame section IF2 is referred to as a second print image IPM2. Furthermore, the print image obtained by imaging the print image data IP received during the (k-1)-th print frame section IFk-1 is referred to as a (k-1)-th print image IPMk-1, and the print image obtained by imaging the print image data IP received during the k-th print frame section IFk is referred to as a k-th print image IPMk.

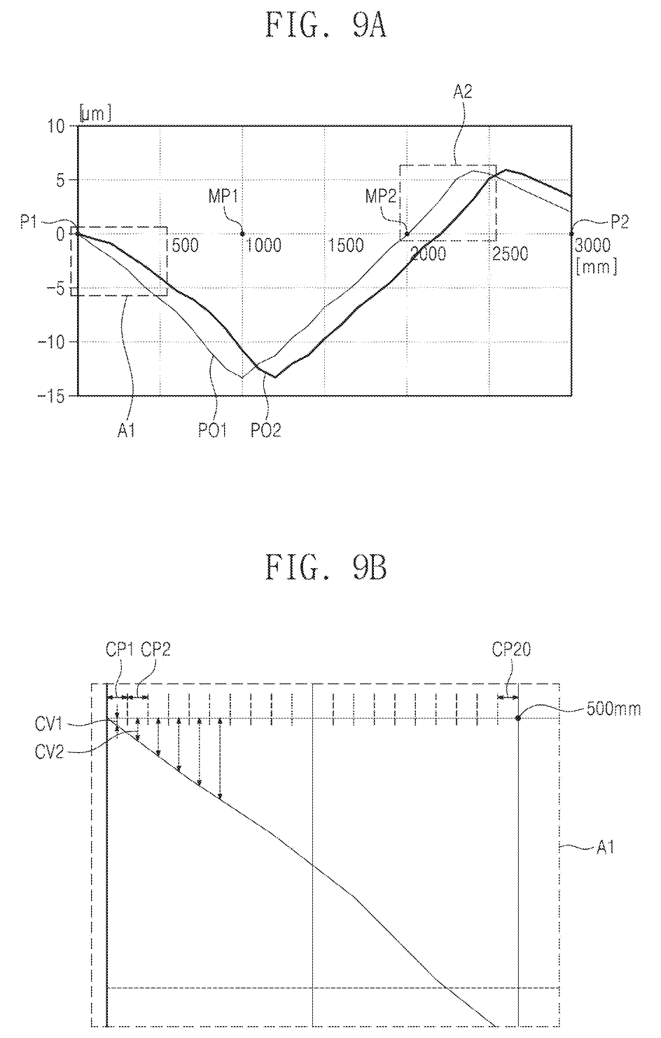

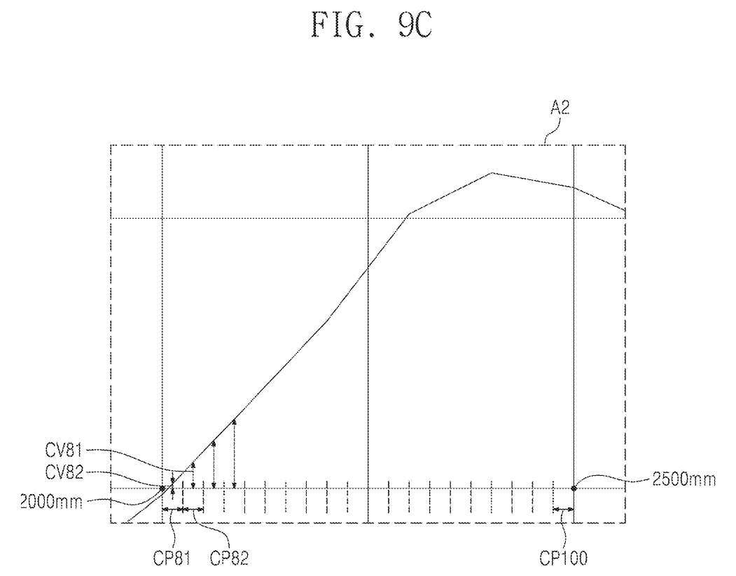

The first print image IPM1 may include a data area CDA and a first command area CA1. The data area CDA may include the plurality of grayscale areas GA. As an example of the present disclosure, the grayscale areas GA included in the data area CDA may be arranged in a 14x4 matrix. The grayscale areas GA included in the data area CDA may include information regarding a correction amount (or correction parameter) with respect to a position. FIG. 8 illustrates a case where four grayscale areas express information regarding the correction amount for each correction section illustrated in FIGS. 9B and 9C. However, the present disclosure is not limited thereto. The number of grayscale areas GA expressing information regarding the correction amount for each correction section may vary depending on the correction range and correction precision.

As an example of the present disclosure, the first command area CA1 may be located to one side of the data area CDA. In the first print image IPM1, the first command area CA1 may be located to the left side of the data area CDA.

The first command area CA1 may include the plurality of grayscale areas GA. As an example of the present disclosure, the grayscale areas GA included in the first command area CA1 may be arranged in a 4X2 matrix. The grayscale areas GA (hereinafter, referred to as command grayscale areas) included in the first command area CA1 may include a first command that determines whether to set a correction amount (or correction parameter) (or may be referred to as initiating a compensation setting operation). As an example of the present disclosure, two command grayscale areas (hereinafter, referred to as a first command grayscale area CGA1 and a second command grayscale area CGA2) may be arranged in the first command area CA1. Among the first and second command grayscale areas CGA1 and CGA2, the first command grayscale area CGA1 may have a white grayscale, and the second command grayscale area CGA2 may have a black grayscale. This may indicate that the first command is recognized as “01”, and “01” initiates setting of the correction amount.

Meanwhile, both the first and second command grayscale areas CGA1 and CGA2 may have a white grayscale. This may indicate that the first command is recognized as “00”, and “00” does not initiate setting of the correction amount.

Meanwhile, the second to (k-1)-th print images IPM2 to IPMk-1 may not include the command area, but only the data area CDA. That is, all grayscale areas GA in the second to (k-1)-th print images IPM2 to IPMk-1 may be utilized as the data areas CDA.

The k-th print image IPMk may include the data area CDA and a second command area CA2. In the k-th print image IPMk, the second command area CA2 is located to one side of the data area CDA. As an example of the present disclosure, the second command area CA2 in the k-th print image IPMk may be located to the right side of the data area CDA.

The command grayscale areas GA included in the second command area CA2 may include a second command that determines whether to terminate setting of the correction amount. As an example of the present disclosure, each row may be configured with two command grayscale areas (hereinafter referred to as a third command grayscale area CGA3 and a fourth command grayscale area CGA4). Both the third and fourth command grayscale areas CGA3 and CGA4 may have black grayscales. This may indicate that the second command is recognized as “11”, and “11” initiates setting of the correction amount. For example, when the second command is “00”, this may indicate that setting of the correction amount is not initiated.

Once the correction amount setting operation is completed during the first to k-th print frame sections IF1 to IFk, an ink ejection operation that ejects ink according to the correction position may be initiated.

The image analysis unit 120 may analyze the print image data IP to extract information on the correction amount for each position of the inkjet head IH. The extracted correction amount may be stored in the parameter storage unit 140. In detail, when the first command is “01”, the image analysis unit 120 initiates the operation of storing the correction amount in the parameter storage unit 140. When the second command is “11”, the image analysis unit 120 terminates the operation of storing the correction amount in the parameter storage unit 140.

When the first command is “00”, the image analysis unit 120 may proceed directly with the ink ejection operation without initiating the operation of storing the correction amount in the parameter storage unit 140.

The signal correction unit 150 may receive the position signal PS from the head interface 110 and may correct the position signal PS based on the correction amount for each position stored in the parameter storage unit 140. That is, the signal correction unit 150 may correct the position signal PS into a correction position signal C_PS based on the correction amount for each position.

The mask unit 130 may receive the print image data IP from the image analysis unit 120 and may perform masking processing on a portion of the print image data IP indicating the first or second commands (i.e., the first or second command area CA1 or CA2) to generate compensation print image data C_IP. Through masking processing, information regarding the first or second command may be removed from the print image data IP. Therefore, the compensation print image data C_IP may only include information regarding the amount of ink ejected from each nozzle NZ.

Meanwhile, the mask unit 130 may perform entire masking processing on the print image data IP during the correction amount setting operation (i.e., during the compensation setting operation). That is, the mask unit 130 may perform entire masking processing on the print image data IP to generate entire masking data M_IP. Accordingly, the inkjet head IH may not eject ink during the correction amount setting operation.

The inkjet head IH receives the entire masking data M_IP or the compensation print image data C_IP from the mask unit 130 and receives the correction position signal C_PS from the signal correction unit 150. Therefore, the inkjet head IH may set the ink ejection amount of each nozzle NZ based on the compensation print image data C_IP, and may set the position of the inkjet head based on the correction position signal C_PS.

In this way, the inkjet head IH may expose ink at a relatively accurate position by setting the position of the inkjet head IH in response to the correction position signal C_PS, thereby relatively improving the reliability of the inkjet process.

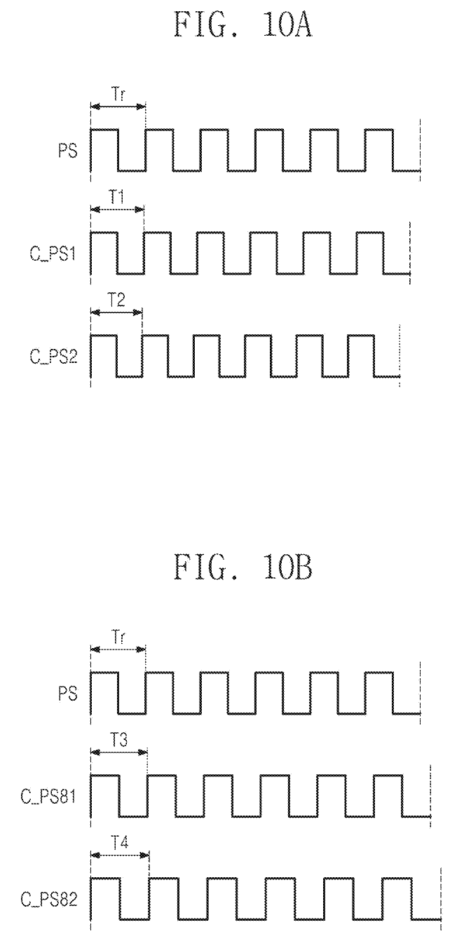

FIG. 9A is a graph illustrating a position error for each of a first inkjet head and a second inkjet head among inkjet heads, according to some embodiments of the present disclosure. FIG. 9B is an enlarged graph illustrating area A1 illustrated in FIGS. 9A, and 9C, is an enlarged graph illustrating area A2 illustrated in FIG. 9A. FIG. 10A is a waveform diagram illustrating correction position signals corresponding to first and second compensation sections illustrated in FIG. 9B, respectively, and FIG. 10B is a waveform diagram illustrating 81st and 82nd correction position signals corresponding to 81st to 82nd compensation sections illustrated in FIG. 9C.

In FIG. 9A, a first graph PO1 represents the position error associated with the first inkjet head, and a second graph PO2 represents the position error associated with the second inkjet head.

Referring to FIGS. 6A and 9A, the support table STB may move from a first position (or an initial position) P1 to a second position (or a final position) P2 in the first-axis direction MD1. As an example of the present disclosure, the distance between the second position P2 and the first position P1 may be 3000 millimeters (mm) (or about 3000 mm). In FIG. 9A, the first position P1 is indicated as about 0mm, and the second position P2 is indicated as 3000 mm (or about 3000 mm).

When the support table STB moves from the first position P1 to the second position P2, the position error may occur between the support table STB and the inkjet heads. When the distance between the first position P1 and the second position P2 is referred to as the entire movement section, the entire movement section may include the plurality of correction sections. As an example of the present disclosure, when the correction section is set to 25 mm (or about 25 mm), the entire movement section may include 120 correction sections.

According to some embodiments of the present disclosure, as the support table STB moves from the first position P1 to a first intermediate position MP1 (e.g., 1000mm), the position error between the support table STB and the first inkjet head increases. Furthermore, as the support table STB moves from the first intermediate position MP1 to a second intermediate position MP2 (e.g., 2000mm), the position error between the support table STB and the first inkjet head decreases. In the section from the first position P1 to the second intermediate position MP2, the distance from the first position P1 to the actual position of the support table STB may be less than the distance from the first position P1 to the target position. In the section from the first position P1 to the second intermediate position MP2, a negative positional error may occur between the first inkjet head and the support table STB. Therefore, this section may be referred to as a negative correction section.

Meanwhile, in the section from the second intermediate position MP2 to the second position P2, the distance from the first position P1 to the actual position of the support table STB may be greater than the distance from the first position P1 to the target position. A positive position error may occur between the first inkjet head and the support table STB in the section from the second intermediate position MP2 to the second position P2. Therefore, this section may be referred to as a positive correction section.

The negative correction section of the first inkjet head may include 80 correction sections, i.e., the first to the 80th correction sections, and the positive correction section of the first inkjet head may include the 81st to the 120th correction sections. As an example of the present disclosure, FIG. 9B illustrates the first to twentieth correction sections CP1 and CP2 to CP20, and FIG. 9C illustrates the 81st to the 100th correction sections CP81 and CP82 to CP100.

When the support table STB is located in the first correction section CP1, a first correction position signal C_PS1 provided to the first inkjet head (refer to FIG. 10A) may be generated based on a first correction amount CV1. When the support table STB is located in the second correction section CP2, a second correction position signal C_PS2 provided to the first inkjet head (refer to FIG. 10B) may be generated based on a second correction amount CV2. As an example of the present disclosure, the first correction amount CV1 may be set to a value corresponding to the average of the position errors between the support table STB and the first inkjet head in the first correction section CP1, and the second correction amount CV2 may be set to a value corresponding to the average of the position errors between the support table STB and the first inkjet head in the second correction section CP2.

Referring to FIG. 10A, the position signal PS may be a square wave generated with a reference period Tr. The first correction position signal C_PS1 may be a square wave having a first period T1 less than the reference period Tr. The first period T1 may be set based on the first correction amount CV1 illustrated in FIG. 9B. The second correction position signal C_PS2 may be a square wave having a second period T2 less than the reference period Tr. The second period T2 may be set based on the second correction amount CV2 illustrated in FIG. 9B. According to some embodiments of the present disclosure, the second period T2 may be less than the first period T1.

When the support table STB is positioned in the 81st correction section CP81, a 81st correction position signal C_PS81 (refer to FIG. 10B) provided to the first inkjet head may be corrected by 81st correction amount CV81, and when the support table STB is positioned in the 82nd correction section CP82, a 82nd correction position signal C_PS82 (refer to FIG. 10B) provided to the first inkjet head may be corrected by 82nd correction amount CV82. As an example of the present disclosure, the 81st correction amount CV81 may be set to a value corresponding to the average of the position errors between the support table STB and the first inkjet head in the 81st correction section CP81, and the 82nd correction amount CV82 may be set to a value corresponding to the average of the position errors between the support table STB and the first inkjet head in the 82nd correction section CP82.

Referring to FIG. 10B, the 81st correction position signal C_PS81 may be a rectangular wave having a third period T3 greater than the reference period Tr. The third period T3 may be set based on the 81st correction amount CV81 illustrated in FIG. 9C. The 82nd correction position signal C_PS82 may be a rectangular wave having a fourth period T4 greater than the reference period Tr. The fourth period T4 may be set based on the 82nd correction amount CV82 illustrated in FIG. 9C. In an example of the present disclosure, the fourth period T4 may be greater than the third period T3.

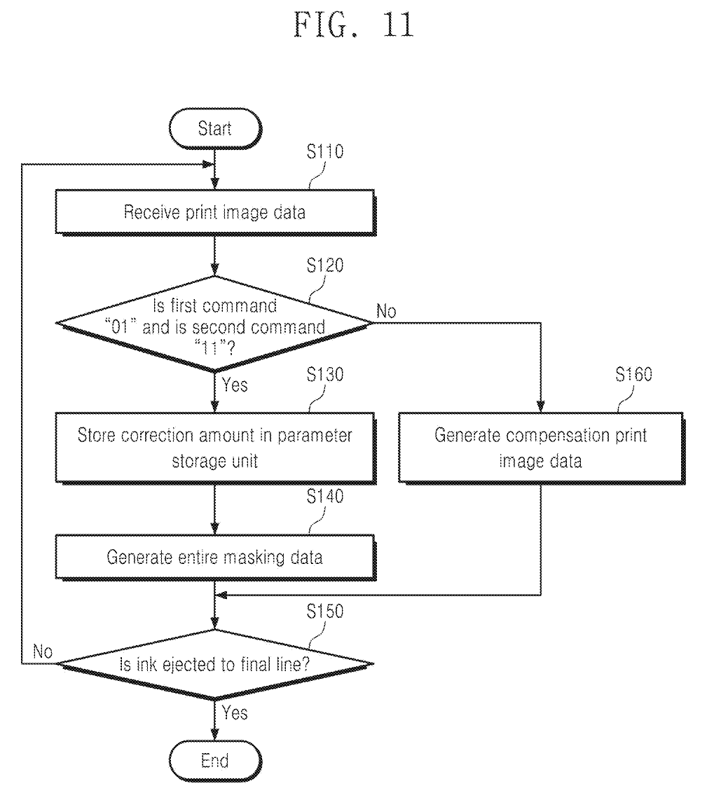

FIG. 11 is a flowchart illustrating aspects of the operation of an inkjet printing apparatus, according to some embodiments of the present disclosure. Although FIG. 11 illustrates various operations in the operation of an inkjet printing apparatus, embodiments according to the present disclosure are not limited thereto, and according to some embodiments, the operation of an inkjet printing apparatus may include additional operations, or fewer operations, or the order of operations may vary, unless otherwise stated or implied, without departing from the spirit and scope of embodiments according to the present disclosure.

Referring to FIGS. 7 and 11, the head units HU1 to HUn in the inkjet printing apparatus IPD receive the print image data IP (S110). The head units HU1 to HUn extract the first command from the print image data IP through the image analysis unit 120 and determine whether to initiate the compensation setting operation based on the first command and the second command (S120). Specifically, the head units HU1 to HUn may determine whether the first command is “01” and whether the second command is “11”. When the first command is “01” and the second command is “11”, the compensation setting operation is initiated. When the first command is not “01” or the second command is not “11”, the compensation setting operation may not be initiated.

When the compensation setting operation is initiated, the image analysis unit 120 may extract a correction amount from the print image data IP and may store the extracted correction amount in the parameter storage unit 140 (S130). During the compensation setting operation, the mask unit 130 may perform entire masking process on the print image data IP to generate the entire masking data M_IP (S140).

Meanwhile, in operation S120, when the first command is not “01” or the second command is not “11”, the head units HU1 to HUn may not initiate the compensation setting operation. For example, the image analysis unit 120 provides the print image data IP to the mask unit 130, and the mask unit 130 may perform masking processing on a portion of the print image data IP indicating the first or second command (i.e., the first or second command area CA1 or CA2) to generate compensation print image data C_IP (S160).

The inkjet head IH may receive the entire masking data M_IP or the compensation print image data C_IP from the mask unit 130, and may eject ink from each nozzle NZ based on the compensation print image data C_IP. Meanwhile, when the inkjet head IH receives the entire masking data M_IP from the mask unit 130, the inkjet head IH may not eject ink from each nozzle NZ.

Thereafter, the inkjet head IH determines whether ink is ejected to the final line (S150). When ink is ejected to the final line, the operation ends, and when ink is not ejected to the final line, the operation moves to operation S110 to continue receiving the print image data IP.

The electronic device according to some embodiments may be applied to various electronic devices. The electronic device according to some embodiments includes the electronic device described above, and may further include modules or devices with additional functions.

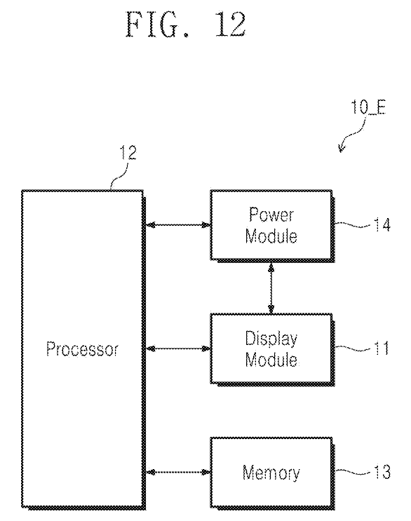

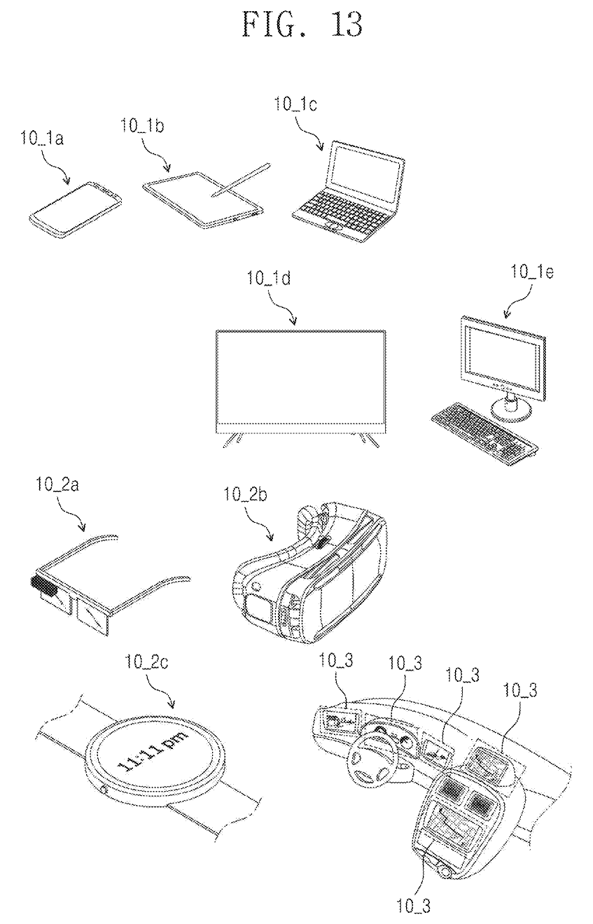

FIG. 12 is a block diagram of an electronic device according to some embodiments.

Referring to FIG. 12, an electronic device 10_E according to some embodiments may include a display module 11, a processor 12, a memory 13, and a power module 14. The display module 11 may correspond to the display module DM described above.

The processor 12 may include at least one of a central processing unit (CPU), an application processor (AP), a graphics processing unit (GPU), a communication processor CP, an image signal processor (ISP), or a controller.

The memory 13 may store data information necessary for operations of the processor 12 or the display module 11. When the processor 12 executes an application stored in the memory 13, an image data signal and/or an input control signal is transferred to the display module 11, and the display module 11 may process the received signal and may output image information through a display screen.

The power module 14 may include a power supply module, such as a power adapter or a battery device, and a power conversion module that converts power supplied by the power supply module to generate power required for the operation of the electronic device 10_E.

At least one of the components of the electronic device 10_E described above may be included in the electronic device according to the embodiments described above. In addition, some of the individual modules functionally included in one module may be included in the electronic device, and others may be provided separately from the electronic device. For example, the electronic device may include the display module 11, and the processor 12, the memory 13, and the power module 14 may be provided in the form of another device within the electronic device 10_E other than the electronic device.

FIG. 13 is a schematic diagram illustrating electronic devices, according to various embodiments.

Referring to FIG. 13, various electronic devices to which the electronic device according to the embodiments is applied may include not only image display electronic devices such as a smart phone 10_1a, a tablet PC 10_1b, a laptop computer 10_1c, a TV 10_1d, a desk monitor 10_1e, but also wearable electronic devices including display modules such as smart glasses 10_2a, a head-mounted display 10_2b, a smart watch 10_2c, etc., and vehicle electronic devices 10_3 including display modules such as a CID (Center Information Display) placed on an instrument panel, a center fascia, or a dashboard of a vehicle, a room mirror display, etc.

According to embodiments of the present disclosure, the head unit may relatively accurately expose ink by setting the position of the inkjet head in response to the correction position signal, thereby relatively improving the reliability of the inkjet process.

In addition, because information regarding the correction amount used to correct the position signal is included in the print image data and provided to the head unit, the time required to set the position of the inkjet head may be reduced, thereby reducing the overall process time.

Although aspects of some embodiments of the present disclosure have been described above with reference to embodiments thereof, it will be understood by those skilled in the art or having ordinary knowledge in the art that various modifications and substitutions are possible, without departing from the spirit and the technical scope of the present disclosure as set forth in the claims below.

Accordingly, the technical scope of the present disclosure is not limited to the detailed description of this specification, but should be defined by the appended claims, and their equivalents.

What is claimed is:

1. An inkjet printing apparatus comprising:
a stage;
a support table on the stage and to which a target substrate is fixed;
a first mover configured to move the support table in a first-axis direction on the stage;
a head component on the target substrate and including an inkjet head configured to eject ink onto a printing area of the target substrate; and
a second mover configured to move the head component in a second-axis direction, and
wherein the head component is configured to receive print image data including a position signal indicating a position of the support table and information on a correction amount of the position signal, and to correct the position signal based on the correction amount.

2. The inkjet printing apparatus of claim 1, wherein the head component further includes:
an image analyzer configured to receive the print image data, and to analyze the print image data to extract the correction amount;
a parameter storage component configured to store the correction amount; and
a signal corrector configured to receive the position signal, and to correct the position signal into a correction position signal based on the correction amount provided from the parameter storage component.

3. The inkjet printing apparatus of claim 2, wherein the print image data further includes information on first and second commands configured to initiate a compensation setting operation, and
wherein based on the head component initiating the compensation setting operation according to the first and second commands, the image analyzer is configured to store the correction amount in the parameter storage component.

4. The inkjet printing apparatus of claim 3, wherein the head component further includes:
a mask component configured to receive the print image data from the image analyzer and to output compensation print image data by masking the first and second commands among the print image data.

5. The inkjet printing apparatus of claim 4, wherein a print image obtained by imagining the print image data includes a data area and a command area,
wherein the data area includes a plurality of grayscale areas indicating information about the correction amount, and
wherein the command area includes a plurality of command grayscale areas indicating information about the first command or the second command.

6. The inkjet printing apparatus of claim 4, wherein the mask component is configured to generate entire masking data by performing entire masking processing on the print image data received during the compensation setting operation.

7. The inkjet printing apparatus of claim 2, wherein the position signal is a square wave signal generated with a reference period,
wherein the correction position signal has a period different from the reference period, and
wherein the period of the correction position signal is set depending on the correction amount.

8. The inkjet printing apparatus of claim 7, wherein based on a distance between an actual position of the support table and an initial position of the support table in the first-axis direction being less than a distance between a target position of the support table and the initial position of the support table,
the period of the correction position signal is less than the reference period.

9. The inkjet printing apparatus of claim 7, wherein based on a distance between an actual position of the support table and an initial position of the support table in the first-axis direction being greater than a distance between a target position of the support table and the initial position of the support table,
the period of the correction position signal is greater than the reference period.

10. The inkjet printing apparatus of claim 1, wherein the inkjet head includes a plurality of nozzles arranged on one surface of the inkjet head, and
wherein the plurality of nozzles include an active nozzle configured to eject the ink and an inactive nozzle that is configured to not eject the ink.

11. A method of driving an inkjet printing apparatus comprising:
receiving print image data through a head component;
extracting a first command from the print image data and determining whether to initiate a compensation setting operation based on the first command;
based on the compensation setting operation being initiated, extracting a correction amount from the print image data and storing the extracted correction amount in a parameter storage component;
masking the print image data through a mask component to generate entire masking data;
extracting a second command from the print image data and determining whether to terminate the compensation setting operation based on the second command; and
based on the compensation setting operation not being initiated, masking portions of the print image data indicating the first and second commands through the mask component to generate compensation print image data.

12. The method of claim 11, wherein the head component includes an inkjet head and a plurality of nozzles on a lower surface of the inkjet head, and
wherein the inkjet head receives the entire masking data to stop an ink ejection operation, and receives the compensation print image data to eject the ink through an activated nozzle among the plurality of nozzles.

13. The method of claim 11, further comprising:
receiving a position signal through the head component, and correcting the position signal into a correction position signal based on the correction amount provided from the parameter storage component.

14. The method of claim 13, wherein the position signal is a square wave signal generated with a reference period,
wherein the correction position signal has a period different from the reference period, and
wherein the period of the correction position signal is set depending on the correction amount.

15. The method of claim 14, wherein the inkjet printing apparatus includes:
a stage;
a support table on the stage and to which a target substrate is fixed;
a first mover configured to move the support table in a first-axis direction on the stage;
a second mover configured to move the head component in a second-axis direction, and
wherein the head component includes an inkjet head on the target substrate and configured to eject ink onto a printing area of the target substrate.

16. The method of claim 15, wherein when a distance between an actual position of the support table and an initial position of the support table in the first-axis direction is less than a distance between a target position of the support table and the initial position of the support table,
the period of the correction position signal is less than the reference period.

17. The method of claim 15, wherein based on a distance between an actual position of the support table and an initial position of the support table in the first-axis direction being greater than a distance between a target position of the support table and the initial position of the support table,
the period of the correction position signal is greater than the reference period.

18. An electronic device comprising:
a display module configured to display an image; and
a processor configured to process an image signal so as to provide image data to the display module, and
wherein the display module is manufactured using an inkjet printing apparatus, and
wherein the inkjet printing apparatus includes:
a stage;
a support table on the stage and to which a target substrate is fixed;
a first mover configured to move the support table in a first-axis direction on the stage;
a head component on the target substrate and including an inkjet head configured to eject ink onto a printing area of the target substrate; and
a second mover configured to move the head component in a second-axis direction, and
wherein the head component is configured to receive print image data including a position signal indicating a position of the support table and information on a correction amount of the position signal, and to correct the position signal based on the correction amount.

19. The electronic device of claim 18, wherein the head component further includes:
an image analyzer configured to receive the print image data, and to analyze the print image data to extract the correction amount;
a parameter storage component configured to store the correction amount; and
a signal corrector configured to receive the position signal, and to correct the position signal into a correction position signal based on the correction amount provided from the parameter storage component.

20. The electronic device of claim 19, wherein the print image data further includes information on first and second commands configured to initiate a compensation setting operation, and
wherein when the head component is configured to initiate the compensation setting operation according to the first and second commands, the image analyzer is configured to store the correction amount in the parameter storage component.
